(19) United States
(12) Patent Application Publication
(10) Pub. No.: US 2024/0038932 A1
(43) Pub. Date: Feb. 1, 2024

(54) NITRIDE SEMICONDUCTOR LIGHT-EMITTING DEVICE

(71) Applicant: Ushio Denki Kabushiki Kaisha, Chiyoda-ku, Tokyo, (JP)

(72) Inventor: Toshihiko Fukamachi, Tokyo (JP)

(73) Assignee: Ushio Denki Kabushiki Kaisha, Chiyoda-ku, Tokyo, (JP)

(21) Appl. No.: 18/267,245

(22) PCT Filed: Dec. 13, 2021
(86) PCT No.: PCT/JP2021/045852

§ 371 Date: Jun. 14, 2023

(30) Foreign Application Priority Data
Jan. 28, 2021 (JP) 2021-011771

(51) Int. Cl. H01L 33/32; H01L 33/42; H01L 33/14

(52) U.S. Cl. CPC H01L 33/32; H01L 33/42; H01L 33/145; H01L 33/0075

(57) ABSTRACT

A nitride semiconductor light-emitting device includes: a first conductivity-type nitride semiconductor layer, an active layer located over the first conductivity-type nitride semiconductor layer, a second conductivity-type nitride semiconductor layer located over the active layer, a current constriction layer located in a part of the second conductivity-type nitride semiconductor layer, and a transparent conductive layer located on the second conductivity-type nitride semiconductor layer and transparent to light generated from the active layer.

### TECHNICAL FIELD

The present disclosure relates to a nitride semiconductor light-emitting device.

### BACKGROUND ART

Blue-violet laser diodes are increasingly being adopted as light sources for lithography equipment. Blue-violet laser diodes need to have higher output power and higher reliability and need to suppress heat generation and achieve higher slope efficiency. Patent Document 1 discloses a method of sequentially forming a p-type GaN guide layer, a p-type AlGaN cladding layer, and a p-type GaN contact layer on an active layer.

### CITATION LIST

Patent Document 1: Japanese Patent No. 3785970

### SUMMARY OF INVENTION

### Technical Problem

However, in the configuration disclosed in Patent Document 1, a p-type GaN contact layer is provided to be in contact with a p-side electrode. Hence, the vertical transverse mode of the laser beam is shifted toward the p-type GaN contact layer, resulting in a decrease in the amplification efficiency of the laser beam. In addition, in the configuration disclosed in Patent Document 1, if the p-type AlGaN cladding layer is thin, the vertical transverse mode of the laser light propagates the p-side electrode, resulting in an optical loss.

On the other hand, if the p-type AlGaN cladding layer is thickened to prevent the light propagation mode of the laser light from being shifted toward the p-type GaN contact layer or propagating the p-side electrode, the resistance and optical loss are increased to that extent, resulting in an increase in heat generation and a reduction in slope efficiency.

It is an object of the present invention to provide a nitride semiconductor light-emitting device capable of reducing heat generation and improving slope efficiency.

### Solution to Problem

A nitride semiconductor light-emitting device according to an aspect of the present invention includes: a first conductivity-type nitride semiconductor layer, an active layer located over the first conductivity-type nitride semiconductor layer, a second conductivity-type nitride semiconductor layer located over the active layer, a current constriction layer located in a part of the second conductivity-type nitride semiconductor layer, and a transparent conductive layer located on the second conductivity-type nitride semiconductor layer and transparent to light generated from the active layer.

This makes it possible to confine the vertical transverse mode, which is in a direction vertical to the light propagation direction, with the transparent conductive layer while suppressing the second conductivity-type nitride semiconductor layer from being thickened. In addition, this eliminates the need for providing the contact layer for making contact with the electrode on the transparent conductive layer and reduces the resistance on the current injected into the active layer through the transparent conductive layer. Furthermore, this makes it possible to constrict the current injected into the active layer with the current constriction layer, efficiently inject the current into the light-emitting area, and confine the horizontal transverse mode, which is in a direction horizontal to the light propagation direction, between the current constriction layers. Therefore, this reduces optical loss during the light propagation and improves the slope efficiency as well as reduces the heat generation in the nitride semiconductor light-emitting device.

The nitride semiconductor light-emitting device according to an aspect of the present invention may further include an end-face-protective layer formed on each end face of the first conductivity-type nitride semiconductor layer, the active layer, the second conductivity-type nitride semiconductor layer, and the transparent conductive layer.

This makes it possible to reflect the guided light while maintaining the distribution of the vertical transverse mode, thereby reducing optical loss.

In the nitride semiconductor light-emitting device according to an aspect of the present invention, a lower face of the current constriction layer may be set at a position lower than an upper face of the second conductivity-type nitride semiconductor layer.

This makes it possible to constrict the current injected into the active layer with the current constriction layer, enabling the horizontal transverse mode, which is in a direction horizontal to the light propagation direction, to be confined between the current constriction layers while efficiently injecting the current into the light-emitting area.

In addition, in the nitride semiconductor light-emitting device according to an aspect of the present invention, the current constriction layer may be formed to have an opening along a light-waveguide direction in which the light generated from the active layer is guided, and the second conductivity-type nitride semiconductor layer is embedded in the opening.

This makes it possible to confine the horizontal transverse mode, which is in a direction horizontal to the light propagation direction, between the current constriction layers while confining the vertical transverse mode, which is in a direction vertical to the light propagation direction, with the transparent conductive layer, thereby reducing optical loss during light propagation.

A nitride semiconductor light-emitting device according to an aspect of the present invention includes a first conductivity-type nitride semiconductor layer, an active layer located over the first conductivity-type nitride semiconductor layer, a second conductivity-type nitride semiconductor layer located over the active layer, a transparent conductive layer located on the second conductivity-type nitride semiconductor layer and transparent to light generated from the active layer, a current constriction layer located on a part of the transparent conductive layer, and an end-face-protective layer formed on each end face of the first conductivity-type nitride semiconductor layer, the active layer, the second conductivity-type nitride semiconductor layer, and the transparent conductive layer.

This makes it possible to reflect the guided light with the end-face-protective layer while maintaining the distribution of the vertical transverse mode, in addition to making it possible to confine the vertical transverse mode, which is in a direction vertical to the light propagation direction, with the transparent conductive layer while suppressing the second conductivity-type nitride semiconductor layer from being thickened. In addition, this reduces the resistance on the current injected into the active layer through the transparent conductive layer in addition to eliminating the need for providing the contact layer for making contact with the electrode on the transparent conductive layer. Furthermore, this makes it possible to constrict the current injected into the active layer with the current constriction layer and efficiently inject the current into the light-emitting area without performing another crystal growth after the formation of the current constriction layer. Therefore, this reduces optical loss during the light propagation and improves the slope efficiency in addition to reducing the heat generation in the nitride semiconductor light-emitting device while suppressing an increase in the number of processes.

In the nitride semiconductor light-emitting device according to an aspect of the present invention, the transparent conductive layer may be used as at least one of a guide layer or a cladding layer over the active layer.

This makes it possible to remove the guide layer or the cladding layer of the second conductivity-type nitride semiconductor layer while enabling the vertical transverse mode during light propagation to be confined with the transparent conductive layer, thereby reducing the resistance on the current injected into the active layer through the second conductivity-type nitride semiconductor layer.

In the nitride semiconductor light-emitting device according to an aspect of the present invention, the current constriction layer may also be located over a light-emitting section of the active layer on an end-face side of the second conductivity-type nitride semiconductor layer.

This makes it possible to reduce cleavage abnormalities when the nitride semiconductor light-emitting device is cut from a wafer, and also to suppress heat generation on the end face, thereby preventing end-face breakdown.

In the nitride semiconductor light-emitting device according to an aspect of the present invention, the current constriction layer may be located along the light-waveguide direction and is continuous on the end-face side of the second conductivity-type nitride semiconductor layer.

This makes it possible to confine the horizontal transverse mode between the current constriction layers based on a single patterning of the current constriction layers, and to form a current non-injection area on the end-face side, thereby suppressing an increase in the number of processes necessary for fabricating the current non-injection area.

In addition, in the nitride semiconductor light-emitting device according to an aspect of the present invention, the second conductivity-type nitride semiconductor layer may extend between the current constriction layer and the active layer.

This makes it possible to secure a depletion layer necessary for recombination in the second conductivity-type nitride semiconductor layer while making the current constriction layer thinner. Accordingly, the stress applied to the second conductivity-type nitride semiconductor layer caused by the mismatch of lattice constants with the current constriction layer can be reduced without a decrease in luminous efficiency.

In addition, in the nitride semiconductor light-emitting device according to an aspect of the present invention, the first conductivity-type nitride semiconductor layer may be an n-type nitride semiconductor layer, and the second conductivity-type nitride semiconductor layer may be a p-type nitride semiconductor layer.

This enables the use of holes, which have smaller mobility than electrons, as carriers on the current injection side. Hence, this makes it possible to obtain the current constriction effect in the p-type nitride semiconductor layer while making the current constriction layer thinner, thereby reducing the stress applied to the p-type nitride semiconductor layer caused by the mismatch of lattice constants with the current constriction layer.

In addition, in the nitride semiconductor light-emitting device according to an aspect of the present invention, the p-type nitride semiconductor layer at a position where the current constriction layer is absent may have a thickness of 40 nm or more and 550 nm or less.

Setting the thickness of the p-type nitride semiconductor layer to 40 nm or more makes it possible to secure the depletion layer necessary for recombination in the p-type nitride semiconductor layer, thereby preventing a decrease in luminous efficiency. Setting the thickness of the p-type nitride semiconductor layer to 550 nm or less makes it possible to reduce the resistance on the current injected into the active layer through the p-type nitride semiconductor layer, thereby reducing the heat generation in the nitride semiconductor light-emitting device.

In addition, in the nitride semiconductor light-emitting device according to an aspect of the present invention, the first conductivity-type nitride semiconductor layer may be a p-type nitride semiconductor layer and the second conductivity-type nitride semiconductor layer may be an n-type nitride semiconductor layer.

This makes it possible to confine the vertical transverse mode, which is in a direction vertical to the light propagation direction, with the transparent conductive layer while suppressing the n-type nitride semiconductor layer from being thickened, thereby reducing optical loss during the light propagation and improving the slope efficiency in addition to reducing the heat generation in the nitride semiconductor light-emitting device.

In addition, in the nitride semiconductor light-emitting device according to an aspect of the present invention, the n-type nitride semiconductor layer at a position where the current constriction layer is absent may have a thickness of 5 nm or more and 150 nm or less.

Setting the thickness of the n-type nitride semiconductor layer to 5 nm or more makes it possible to secure the depletion layer necessary for recombination in the n-type nitride semiconductor layer, thereby preventing a decrease in luminous efficiency. Setting the thickness of the n-type nitride semiconductor layer to 150 nm or less makes it possible to reduce the resistance on the current injected into the active layer through the n-type nitride semiconductor layer, thereby reducing the heat generation in the nitride semiconductor light-emitting device.

In addition, in the nitride semiconductor light-emitting device according to an aspect of the present invention, the transparent conductive layer may contain at least one element selected from among In, Sn, Zn, Ti, Nb, and Zr.

This makes it possible to form a transparent conductive layer transparent to the light generated from the active layer while ensuring conductivity.

In addition, in the nitride semiconductor light-emitting device according to an aspect of the present invention, the transparent conductive layer may be thinned in a range in which a vertical transverse mode can be confined during light propagation.

This makes it possible to confine the vertical transverse mode, which is in a direction vertical to the light propagation direction, with the transparent conductive layer while suppressing the second conductivity-type nitride semiconductor layer from being thickened, and also to reduce the resistance on the current injected into the active layer through the transparent conductive layer. Therefore, this makes it possible to reduce optical loss during the light propagation in addition to reducing the heat generation in the nitride semiconductor light-emitting device, thereby improving the slope efficiency.

In addition, in the nitride semiconductor light-emitting device according to an aspect of the present invention, the transparent conductive layer may have a thickness of 80 nm or more and 120 nm or less.

Setting the thickness of the transparent conductive layer to 80 nm or more makes it possible to confine the vertical transverse mode, which is in a direction vertical to the light propagation direction, with the transparent conductive layer. Setting the thickness of the transparent conductive layer to 120 nm or less makes it possible to reduce the resistance on the current injected into the active layer through the transparent conductive layer.

### Effects of the Invention

An aspect of the present invention is capable of reducing the heat generation in the nitride semiconductor light-emitting device and improving the slope efficiency.

### BRIEF DESCRIPTION OF DRAWINGS

FIG. 1 is a cross-sectional view illustrating a configuration of a nitride semiconductor light-emitting device according to a first embodiment, the configuration being cut perpendicular in a light-waveguide direction.

FIG. 2A is a cross-sectional view illustrating a configuration of the nitride semiconductor light-emitting device according to the first embodiment, cut along the light-waveguide direction.

FIG. 2B is a diagram illustrating a refractive index of each layer of the nitride semiconductor light-emitting device according to the first embodiment.

FIG. 3A is a cross-sectional view illustrating an example of a method of manufacturing the nitride semiconductor light-emitting device according to the first embodiment.

FIG. 3B is a cross-sectional view illustrating an example of a method of manufacturing the nitride semiconductor light-emitting device according to the first embodiment.

FIG. 3C is a plan view illustrating a configuration example of a current constriction layer of the nitride semiconductor light-emitting device according to the first embodiment.

FIG. 3D is a cross-sectional view illustrating an example of a method of manufacturing the nitride semiconductor light-emitting device according to the first embodiment.

FIG. 4 is a diagram illustrating an example of a simplified model for calculating a built-in potential of the nitride semiconductor light-emitting device according to the first embodiment.

FIG. 5 illustrates simulation results of a propagation mode of the nitride semiconductor light-emitting device according to the first embodiment.

FIG. 6A is a cross-sectional view illustrating a configuration of the nitride semiconductor light-emitting device according to a comparative example, cut along the light-waveguide direction.

FIG. 6B is a diagram illustrating the refractive index of each layer of the nitride semiconductor light-emitting device according to the comparative example.

FIG. 7A illustrates an example of simulation results of a propagation mode of the nitride semiconductor light-emitting device according to the comparative example.

FIG. 7B illustrates another example of simulation results of a propagation mode of the nitride semiconductor light-emitting device according to the comparative example.

FIG. 8 is a cross-sectional view illustrating an implementation example of the nitride semiconductor light-emitting device according to the first embodiment.

FIG. 9 is a cross-sectional view illustrating a configuration of a nitride semiconductor light-emitting device according to a second embodiment, the configuration being cut perpendicular to the light-waveguide direction.

FIG. 10 is a cross-sectional view illustrating a configuration of a nitride semiconductor light-emitting device according to a third embodiment, cut perpendicular to the light-waveguide direction.

FIG. 11A is a cross-sectional view illustrating an example of a method of manufacturing the nitride semiconductor light-emitting device according to the third embodiment.

FIG. 11B is a cross-sectional view illustrating an example of a method of manufacturing the nitride semiconductor light-emitting device according to the third embodiment.

### DETAILED DESCRIPTION OF THE EMBODIMENTS

Hereinafter, the detailed description of the present embodiments of the invention will be described with reference to the accompanying drawings. The following embodiments are not intended to limit the present invention, and all of the combinations of features described in the embodiments may not be essential to the configuration of the present invention. The configuration of the present embodiment may be modified or changed as appropriate depending on the specifications of the device to which the invention is applied and various conditions (conditions of use, environment of use, etc.). The technical scope of the present invention is determined by the claims and is not limited by the following individual embodiments. The drawings used in the following description may differ in scale and shape from the actual structure in order to facilitate understanding of each configuration.

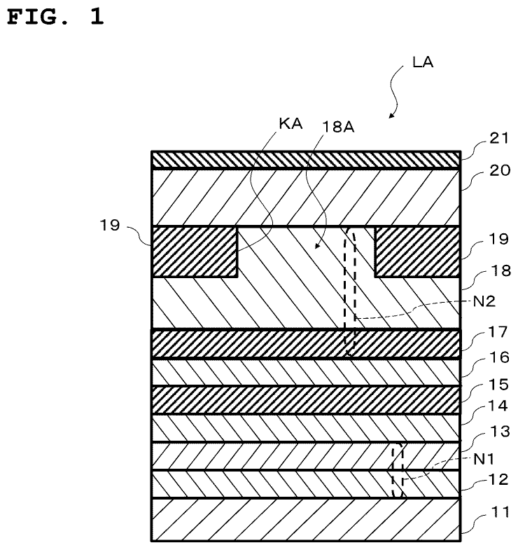

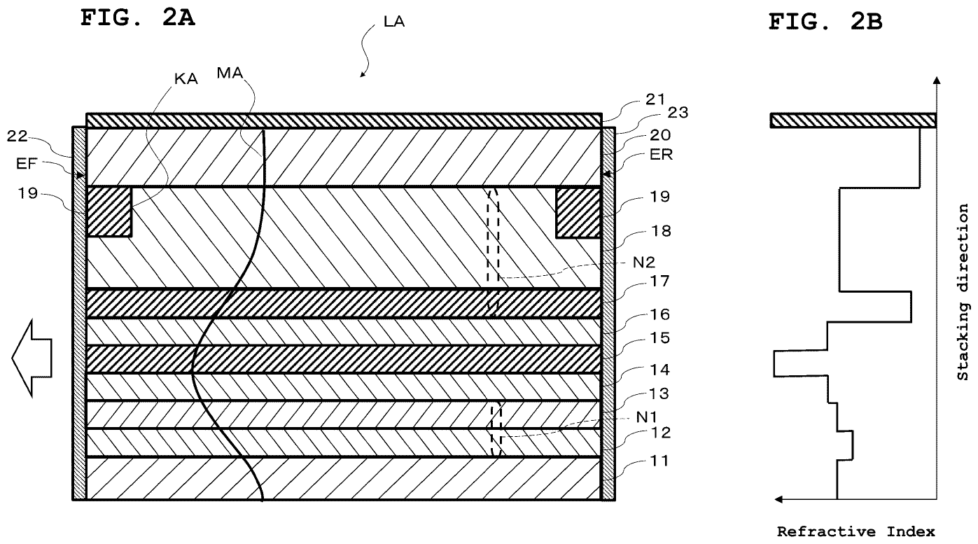

FIG. 1 is a cross-sectional view illustrating a configuration of a nitride semiconductor light-emitting device according to a first embodiment, the configuration being cut perpendicular to a light-waveguide direction. FIG. 2A is a cross-sectional view illustrating a configuration of the nitride semiconductor light-emitting device according to the first embodiment, cut along the light-waveguide direction. FIG. 2B is a diagram illustrating the refractive index of each layer of the nitride semiconductor light-emitting device according to the first embodiment.

In FIGS. 1 and 2A, a semiconductor laser LA includes an n-type nitride semiconductor layer N1, an active layer 15, a p-type nitride semiconductor layer N2, a current constriction layer 19, and a transparent conductive layer 20. The active layer 15 is stacked on the n-type nitride semiconductor layer N1. The p-type nitride semiconductor layer N2 is stacked on the active layer 15. The p-type nitride semiconductor layer N2 preferably has a thickness of 40 nm or more and 550 nm or less. The nitride semiconductor can have a composition of, for example, InₓAl_{y}Ga_{1-x-y}N (0≤x≤1, 0≤y≤1, 0≤x+y≤1).

A non-doped nitride guide layer 14 may be provided between the n-type nitride semiconductor layer N1 and the active layer 15 to suppress the diffusion of impurities from the n-type nitride semiconductor layer N1 to the active layer 15. A non-doped nitride guide layer 16 may be provided between the p-type nitride semiconductor layer N2 and the active layer 15 to suppress the diffusion of impurities from the p-type nitride semiconductor layer N2 to the active layer 15.

The current constriction layer 19 is located in a part of the p-type nitride semiconductor layer N2. Here, the current constriction layer 19 can be located in a part of the p-type nitride semiconductor layer N2 such that at least one resonator of a refractive index waveguide type or a gain waveguide type is configured. The lower face of the current constriction layer 19 can be set at a position lower than the upper face of the p-type nitride semiconductor layer N2. The lower face of the current constriction layer 19 can be set at a position lower than the lower face of the transparent conductive layer 20. In addition, as shown in FIG. 2A, the current constriction layer 19 can also be located over the light-emitting section of the active layer on the end-face side of the p-type nitride semiconductor layer N2. The current constriction layer 19 can also be located such that the p-type nitride semiconductor layer N2 extends between the current constriction layer 19 and the active layer 15. The current constriction layer 19 can be, for example, a high-resistance layer made of AlN. The thickness of the current constriction layer 19 can be set to 100 nm, for example.

The transparent conductive layer 20 is a conductive layer transparent to the light generated in the active layer 15. The transparent conductive layer 20 can have its Fermi level located in the conduction band. The transparent conductive layer 20 is used as at least one of the guide layer or the cladding layer over the active layer 15. The transparent conductive layer 20 can contain at least one element selected from among In, Sn, Zn, Ti, Nb, and Zr, and can be an oxide of these elements. For example, the transparent conductive layer 20 can be an Indium Tin Oxide (ITO) film, a ZnO film, a SnO film, or a TiO film. The transparent conductive layer 20 is preferably thinned in a range in which a vertical transverse mode MA can be confined. The vertical transverse mode MA is a propagation mode in a direction vertical to the light propagation direction. The thickness of the transparent conductive layer 20 is preferably nm or more and 120 nm or less. In the present specification, the p-type nitride semiconductor layer N2 and the transparent conductive layer 20 together may be referred to as a p-side layer.

The n-type nitride semiconductor layer N1 includes an n-type nitride cladding layer 12 and an n-type nitride guide layer 13. The n-type nitride cladding layer 12 and the n-type nitride guide layer 13 are sequentially stacked on the n-type nitride semiconductor substrate 11.

The p-type nitride semiconductor layer N2 includes a p-type carrier block layer 17 and a p-type nitride guide layer 18. The p-type carrier block layer 17 and the p-type nitride guide layer 18 are sequentially stacked on the non-doped nitride guide layer 16. Here, an opening KA may be formed in the current constriction layer 19 to embed a part of the p-type nitride guide layer 18 in the opening KA as a p-type nitride guide layer 18A in order to dispose the current constriction layer 19 in a part of the p-type nitride semiconductor layer N2.

An electrode 21 is formed on the transparent conductive layer 20 to inject current into the active layer 15 through the transparent conductive layer 20 and the p-type nitride semiconductor layer N2. The electrode 21 can have a layered structure of Ti/Pt/Au. The thickness of the Ti/Pt/Au can be set to 100/50/300 nm, for example.

In addition, as shown in FIG. 2A, an end-face-protective layer 22 is formed on an end face EF of the semiconductor laser LA. The end-face-protective layer 22 can have a layered structure of AlN/SiO₂. The thickness of the AlN/SiO₂ can be set to 30/300 nm, for example. An end-face-protective layer 23 is formed on an end face ER of the semiconductor laser LA. The end-face-protective layer 23 can have a layered structure of AlN/(SiO₂/Ta₂O₅)⁶/SiO₂. The thickness of the AlN/(SiO₂/Ta₂O₅)⁶/SiO₂ can be set to 30/(60/40)6/10 nm, for example. The end-face-protective layers 22 and 23 can cover not only the respective end faces of the n-type nitride semiconductor layer N1, the active layer 15, the p-type nitride semiconductor layer N2, and the current constriction layer 19 but also the respective end faces of the transparent conductive layer 20.

As the n-type nitride semiconductor substrate 11, the n-type nitride cladding layer 12, the n-type nitride guide layer 13, the non-doped nitride guide layer 14, the active layer 15, the non-doped nitride guide layer 16, the p-type carrier block layer 17, and the p-type nitride guide layers 18 and 18A, an n-type GaN substrate, an n-type Al_{0.02}Ga_{0.98}N layer, an n-type GaN layer, an In_{0.02}Ga_{0.99}N layer, a single quantum well layer consisting of an In_{0.02}Ga_{0.98}N layer/an In_{0.08}Ga_{0.88}N layer/an In_{0.02}Ga_{0.98}N layer, an In_{0.02}Ga_{0.99}N layer, a p-type Al_{0.22}Ga_{0.78}N, and a p-type GaN layer can be used, respectively.

The thickness of the n-type nitride cladding layer 12 can be set to 700 nm and the donor concentration N D thereof can be set to 1×10¹⁷/cm³, for example. The thickness of the n-type nitride guide layer 13 can be set to 50 nm and the donor concentration N D thereof can be set to 1×10¹⁷/cm³, for example. The thickness of the non-doped nitride guide layer 14 can be set to 136 nm, for example. The thickness of the barrier layer/well layer/barrier layer of the quantum well layer in the active layer 15 can be set to 10/9/10 nm, for example. The thickness of the non-doped nitride guide layer 16 can be set to 135 nm, for example. The thickness of the p-type carrier block layer 17 can be set to 4 nm, for example, and the acceptor concentration N_{A} thereof can be set to 1×10¹⁸/cm³. The thickness of the p-type nitride guide layer 18 and 18A in total can be set to 50 nm, for example, and the acceptor concentration N_{A} thereof can be set to 1×10¹⁸/cm³.

As shown in FIG. 2B, the refractive index of the n-type nitride cladding layer 12 can be smaller than that of the n-type nitride guide layer 13, the refractive index of the n-type nitride guide layer 13 can be smaller than that of the non-doped nitride guide layer 14, and the refractive index of the non-doped nitride guide layer 14 can be smaller than that of the active layer 15. In addition, the refractive index of the transparent conductive layer 20 can be smaller than that of the p-type nitride guide layer 18, the refractive index of the p-type nitride guide layer 18 can be smaller than that of the non-doped nitride guide layer 16, and the refractive index of the non-doped nitride guide layer 16 can be smaller than that of the active layer 15. The refractive index of the transparent conductive layer 20 can be smaller than that of the p-type carrier block layer 17, and the refractive index of the p-type carrier block layer 17 can be smaller than that of the p-type nitride guide layer 18.

As shown in FIG. 2A, the vertical transverse mode MA of the semiconductor laser LA during laser oscillation propagates the transparent conductive layer 20. Here, setting the refractive index of the transparent conductive layer 20 to be smaller than that of the p-type nitride guide layer 18 makes it possible to confine the vertical transverse mode MA with the transparent conductive layer 20 while suppressing the p-type nitride semiconductor layer N2 from being thickened. In addition, stacking the transparent conductive layer 20 on the p-type nitride semiconductor layer N2 eliminates the need for providing a p-type nitride semiconductor contact layer on the transparent conductive layer 20 for making contact with the electrode 21, and also reduces the resistance on the current injected into the active layer 15 through the transparent conductive layer 20. Furthermore, providing the current constriction layer 19 in a part of the p-type nitride semiconductor layer N2 makes it possible to constrict the current injected into the active layer 15 by the current constriction layer 19, thereby efficiently injecting the current into the light-emitting area, and to confine the horizontal transverse mode, which is in a direction horizontal to the light propagation direction, between the current constriction layers 19. This makes it possible to reduce optical loss during the light propagation in addition to reducing the heat generation in the nitride semiconductor laser LA, thereby improving the slope efficiency.

In addition, the end-face-protective layers 22 and 23 cover not only the respective end faces of the n-type nitride semiconductor layer N1, the active layer 15, the p-type nitride semiconductor layer N2, and the current constriction layer 19 but also the respective end faces EF and ER of the transparent conductive layer 20, thereby reflecting the guided light with the end-face-protective layers while maintaining the distribution of the vertical transverse mode MA, resulting in the reduction of optical loss.

Setting the thickness of the p-type nitride semiconductor layer N2 to 40 nm or more makes it possible to secure the depletion layer necessary for recombination in the p-type nitride semiconductor layer N2, thereby preventing a decrease in luminous efficiency. Setting the thickness of the p-type nitride semiconductor layer N2 to 550 nm or less makes it possible to reduce the resistance on the current injected into the active layer 15 through the p-type nitride semiconductor layer N2, thereby reducing the heat generation in the semiconductor laser LA.

Setting the thickness of the transparent conductive layer 20 to 80 nm or more makes it possible to confine the vertical transverse mode MA with the transparent conductive layer 20. Setting the thickness of the transparent conductive layer 20 to 120 nm or less makes it possible to reduce the resistance on the current injected into the active layer 15 through the transparent conductive layer 20.

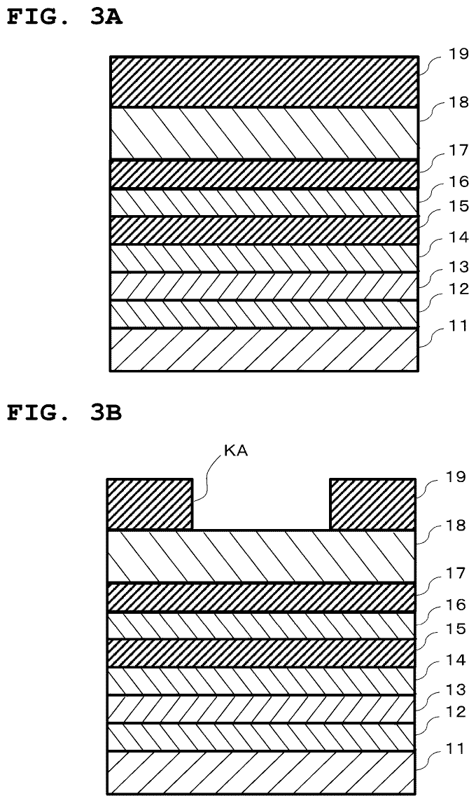

FIGS. 3A, 3B, and 3D each are a cross-sectional view illustrating an example of a method of manufacturing a nitride semiconductor light-emitting device according to the first embodiment, and FIG. 3C is a plan view illustrating a configuration example of a current constriction layer of a nitride semiconductor light-emitting device according to the first embodiment. In FIG. 3A, the n-type nitride cladding layer 12, the n-type nitride guide layer 13, the non-doped nitride guide layer 14, the active layer 15, the non-doped nitride guide layer 16, the p-type carrier block layer 17 and the p-type nitride guide layer 18 are sequentially stacked on the n-type nitride semiconductor substrate 11 by epitaxial growth. Furthermore, the current constriction layer 19 is formed on the p-type nitride semiconductor substrate 18 by a method such as epitaxial growth or sputtering.

Next, as shown in FIG. 3B, the current constriction layer 19 is patterned based on photolithography and dry etching techniques to form the opening KA in the current constriction layer 19. As shown in FIG. 3C, the opening KA can be formed such that the current constriction layer 19 is also located over the light-emitting section of the active layer 15 on the sides of the end faces EF and ER of the semiconductor laser LA. This makes it possible to reduce cleavage abnormalities on the end faces EF and ER when the semiconductor laser LA is cut out of the wafer, and also to suppress heat generation on the end faces EF and ER, thereby preventing end-face breakdown.

In addition, the opening KA can be formed such that the current constriction layer 19 is located on both sides of the resonator between which the laser light is guided and the current constriction layer 19 is continuous on the side of the end faces EF and ER over the light-emitting section of the active layer 15. This makes it possible to confine the horizontal transverse mode between the current constriction layers 19 based on a single patterning of the current constriction layers 19, and to form the current non-injection area on the side of the end-face EF and ER, thereby reducing an increase in the number of processes necessary for fabricating the current non-injection area.

Next, as shown in FIG. 3D, the p-type nitride guide layer 18A is selectively formed on the p-type nitride guide layer 18 in a manner that it is embedded in the opening KA by epitaxial growth.

Next, as shown in FIG. 1, the transparent conductive layer 20 is formed on the p-type nitride guide layer 18A and the current constriction layer 19 by sputtering or other methods. Then, the electrode 21 is formed on the transparent conductive layer 20 by vapor deposition or other methods.

Next, as shown in FIG. 2A, the end faces EF and ER having cleavage faces are formed by cleaving the n-type nitride semiconductor substrate 11. Then, the end-face-protective layers 22 and 23 are formed on each of the end faces EF and ER by sputtering or other methods.

The following will describe an example of the calculation of the thickness of the p-type nitride semiconductor layer N2. The thickness of the p-type nitride semiconductor layer N2 needs to be greater than or equal to a depletion layer thickness w_{P} of the depletion layer formed in the p-type nitride semiconductor layer N2 in order to obtain sufficient characteristics as a diode.

This depletion layer thickness w_{P} is obtained as follows. The nitride semiconductor light-emitting device in the present embodiment has a layer structure of semiconductor: p-type-i-type-n-type. The built-in potential Φ of this pin junction is given by the following Formula 1.

Formula 1

Φ=Φ₁+Φ₂+Φ₃ (1)

Here, Φ1, Φ2, and Φ3 are given by the following Formulas 2 to 4.

$$\begin{matrix}Formula 2 & \\ {Φ}_{1} = - {\int }_{- {w}_{p} - {w}_{1}}^{- {w}_{1}} dz {\int }_{- {w}_{p} - {w}_{1}}^{z} {dz}_{1} \cdot \frac{{ρ}_{p} ( {z}_{1} )}{ε ( {z}_{1} ) \cdot {ε}_{0}} & ( 2 )\end{matrix}$$

$$\begin{matrix}Formula 3 & \\ {Φ}_{2} = - {\int }_{- {w}_{2}}^{- {w}_{2}} dz {\int }_{- {w}_{p} - {w}_{1}}^{{w}_{1}} {dz}_{1} \cdot \frac{{ρ}_{p} ( {z}_{1} )}{ε ( {z}_{1} ) \cdot {ε}_{0}} & ( 3 )\end{matrix}$$

$$\begin{matrix}Formula 4 & \\ {Φ}_{3} = - {\int }_{{w}_{2}}^{{w}_{n} + {w}_{2}} dz {\int }_{{w}_{2}}^{z} {dz}_{3} \cdot \frac{{ρ}_{n} ( {z}_{3} )}{ε ( {z}_{3} ) \cdot {ε}_{0}} & ( 4 )\end{matrix}$$

However, in Formulas 2 to 4, a relationship is given by the following Formula 5.

$$\begin{matrix}Formula 5 & \\ {\int }_{- {w}_{p} - {w}_{1}}^{- {w}_{1}} {dz}_{1} \cdot \vert {ρ}_{p} ( {z}_{1} ) \vert = {\int }_{{w}_{2}}^{{w}_{n} + {w}_{2}} {dz}_{3} \cdot \vert {ρ}_{n} ( {z}_{3} ) \vert & ( 5 )\end{matrix}$$

Here, z is a coordinate indicating the position of the pin junction in the thickness direction, ρₚ and ρₙ are charge amounts per unit volume in each depletion layer of the p-type semiconductor layer and n-type semiconductor layer, respectively, ε is the dielectric constant, co is the dielectric constant of vacuum, w₁ is a z-coordinate at the boundary position between the p-type semiconductor layer and i-type semiconductor layer, w₂ is a z-coordinate at the boundary position between the n-type semiconductor layer and i-type semiconductor layer, wₚ is a depletion layer thickness of the p-type semiconductor layer, and wₙ is a depletion layer thickness of the n-type semiconductor layer. Note that ε, ρₚ, and ρₙ are functions of z.

By solving Formulas 1 to 5 with respect to the actual device structure, the thickness wₚ of the depletion layer formed in the p-type semiconductor is calculated. In the case of the nitride semiconductor light-emitting device of the present embodiment, the built-in potential Φ can be calculated using a simplified model.

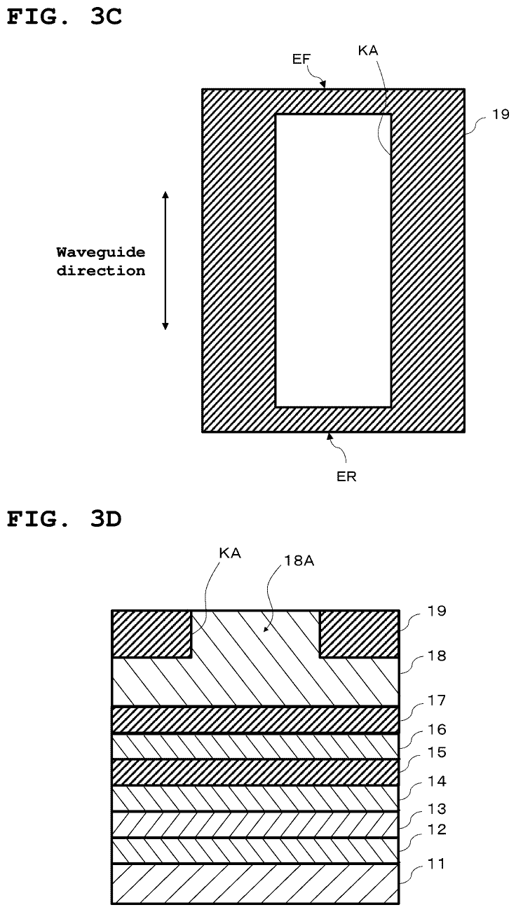

FIG. 4 is a diagram illustrating an example of a simplified model for calculating the built-in potential of the nitride semiconductor light-emitting device according to the first embodiment. In FIG. 4, in this model, the acceptor concentration N_{A} of the p-type semiconductor layer and the donor concentration N_{D} of the p-type semiconductor layer are assumed constant with respect to the z coordinate. The thickness wᵢₙₜᵣ of the i-type semiconductor layer is given by w₁+w₂.

For this model, the built-in potential Φ is given by the following Formula 6.

$$\begin{matrix}Formula 6 & \\ Φ = \frac{q \cdot {N}_{A}}{2 \cdot ε \cdot {ε}_{0}} \cdot {w}_{p}^{2} + \frac{q \cdot {N}_{A}}{ε \cdot {ε}_{0}} \cdot {w}_{p} \cdot {w}_{intr} + \frac{q \cdot {N}_{D}}{2 \cdot ε \cdot {ε}_{0}} \cdot {w}_{n}^{2} & ( 6 )\end{matrix}$$

Next, from Formula (5), the depletion layer thickness wₚ is obtained from the relationship N_{A}×wₚ=N_{D}×wₙ to give the following Formula 7.

$$\begin{matrix}Formula 7 & \\ {w}_{p} = \frac{{N}_{D}}{{N}_{A} + {N}_{D}} \cdot \{ - {w}_{intr} + \sqrt{{w}_{intr}^{2} + \frac{2 \cdot ε \cdot {ε}_{0} \cdot Φ \cdot ( {N}_{A} + {N}_{D} )}{q \cdot {N}_{A} \cdot {N}_{D}}} \} & ( 7 )\end{matrix}$$

Similarly, the depletion layer thickness wₙ is obtained to give the following Formula 8.

$$\begin{matrix}Formula 8 & \\ {w}_{n} = \frac{{N}_{A}}{{N}_{A} + {N}_{D}} \cdot \{ - {w}_{intr} + \sqrt{{w}_{intr}^{2} + \frac{2 \cdot ε \cdot {ε}_{0} \cdot Φ \cdot ( {N}_{A} + {N}_{D} )}{q \cdot {N}_{A} \cdot {N}_{D}}} \} & ( 8 )\end{matrix}$$

In the case of GaN-based semiconductor lasers, Mg is used as a dopant for the p-type semiconductor. However, it is hardly activated because Mg has a deep impurity level; it is enough to be activated by as much as 10%. However, Si is used as a dopant for the n-type semiconductor and is nearly activated by 100%. Accordingly, Formulas 7 and 8 are modified as in Formulas 9 and 10 below, where the activation rate of Mg is a.

$$\begin{matrix}Formula 9 & \\ {w}_{p} = \frac{{N}_{D}}{α \cdot {N}_{A} + {N}_{D}} \cdot \{ - {w}_{intr} + \sqrt{{w}_{intr}^{2} + \frac{2 \cdot ε \cdot {ε}_{0} \cdot Φ \cdot ( α \cdot {N}_{A} + {N}_{D} )}{q \cdot α \cdot {N}_{A} \cdot {N}_{D}}} \} & ( 9 )\end{matrix}$$

$$\begin{matrix}Formula 10 & \\ {w}_{n} = \frac{α \cdot {N}_{A}}{α \cdot {N}_{A} + {N}_{D}} \cdot \{ - {w}_{intr} + \sqrt{{w}_{intr}^{2} + \frac{2 \cdot ε \cdot {ε}_{0} \cdot Φ \cdot ( α \cdot {N}_{A} + {N}_{D} )}{q \cdot α \cdot {N}_{A} \cdot {N}_{D}}} \} & ( 10 )\end{matrix}$$

In addition, GaN-based semiconductor lasers have an internal electric field due to the piezoelectric effect and spontaneous polarization, hence it is preferable to take these effects into account in the above Formulas. Note that the above formulas are derived from a relatively simplified model; however, it has been found empirically to give a rough indication even for GaN-based semiconductor lasers. Accordingly, the depletion layer thickness wₚ (temperature T=25° C.) is specifically obtained from the above formulas. The band gap Eg at a temperature T is given by the following Formula 11.

$$\begin{matrix}Formula 11 & \\ {E}_{g} ( T ) = {E}_{g} ( 0 ) - \frac{a \cdot {T}^{2}}{T + b} & ( 11 )\end{matrix}$$

Note that a and b are constants. From these formulas, the intrinsic carrier density nᵢ is given by Formula 12.

$$\begin{matrix}Formula 12 & \\ {n}_{i} = \sqrt{{N}_{c} \cdot {N}_{i}} \cdot exP ( \frac{{E}_{g} ( T )}{2 \cdot {k}_{B} \cdot T} ) & ( 12 )\end{matrix}$$

Formula 12 yields nᵢ≈8.7×10¹¹/cm³. Note that N_{c}=2.2×10¹⁸/cm³, Nᵥ=4.5×10¹⁹/cm³, E_{g}(0)=3.5 [eV], a=5.08×10⁻⁴ [eV/K], and b=−996 [K], where N_{c} is the effective density of states of the conductor and Nᵥ is the effective density of states of the valence band.

When N_{A}=1.0×10¹⁸/cm³, N_{D}=1.0×10¹/cm³, and α=5[%], the built-in potential Φ is calculated to Φ≈3.2 V from Formula 12 and the following Formula 13.

$$\begin{matrix}Formula 13 & \\ Φ = \frac{{k}_{B} \cdot T}{q} ln ( \frac{α \cdot {N}_{A} \cdot {N}_{D}}{{n}_{i}^{2}} ) & ( 13 )\end{matrix}$$

Accordingly, in the simplified model of FIG. 4, when wᵢₙₜᵣ=300 nm and ε=9.5, the depletion layer thickness wₚ of the p-type semiconductor layer is calculated to wₚ≈91 nm, indicating that the thickness of the p-type semiconductor layer needs to be 91 nm or more.

The above estimates were calculated under the condition of T=25 [° C.]; however in reality, the temperature around the active layer 15 becomes 25° C. or higher due to the heat generated by the energization, which acts in a direction in which the built-in potential Φ becomes smaller. In addition, in the actual usage environment, it is assumed that a situation in which some reverse bias is applied due to handling, etc., may occur, which acts in a direction in which the built-in potential Φ becomes larger. Hence, in order to ensure easy handling and reliable operation of the device, the thickness of the p-type nitride semiconductor layer N2 may be set approximately 150 nm with having a margin.

Here, Formulas 9 and 10 were calculated assuming the case where the p-type and n-type impurity concentrations are spatially uniform. However, if the p-type and n-type impurity concentrations are distributed non-uniformly in space, the spatially averaged impurity concentrations can be applied to Formulas 9 and 10. For a more accurate estimate, Formulas 1 to 5 can be used for calculation.

Next, an example calculation of the thickness of the transparent conductive layer 20 will be described. Consider a three-layer dielectric slab-type waveguide: a p-type cladding layer, a core layer, and an n-type cladding layer. Let the refractive index of the p-type cladding layer be n₃, the refractive index of the core layer be n₁, and the refractive index of the n-type cladding layer be n₂. In this case, light waves propagating in the three-layer dielectric slab waveguide with n₁=n_{core}>n₂=n_{n-clad} and n₁=n_{core}>n₃=n_{p-clad} have a roughly mountain-shaped distribution with its peak around the core layer. In the case of transverse electric (TE) waves, the light distribution E(y) toward the outermost p-type cladding layer is given by Formula 14 below.

Formula 14

E(y)∝exp(−κ·|y|) (14)

Here, K is given by Formula 15 below.

κ=\sqrt{β²−n_{p-clad}²·k₀²} (15)

Here, the propagation constant β is in a range of n_{n-clad}×k₀<β<n_{core}×k₀, where k₀ is the wavenumber of the emitted light and is a constant. Hence, to prevent the disturbance of waveguide mode, the thickness of the outermost cladding layer empirically satisfies the following Formula 16.

Formula 16

2/(k₀·\sqrt{n_{core}²−n_{p-clad}²}) (16)

In the present embodiment, the active layer and the guide layer generally correspond to the core layer and have a total thickness of 500 nm. The refractive index thereof is n_{core}≈2.52 (for GaN) and the refractive index of the p-side layer is n_{clad}≈2.11 at 405 nm. Accordingly, the layer thickness of the transparent conductive layer 20 is preferably 94 nm or more.

The above estimates are for a three-layer dielectric slab-type waveguide; however, it has been found empirically that the same estimates can also be made for the outermost cladding layer in the case of multiple layers beyond three layers. The thickness of the transparent conductive layer 20 is preferably set to approximately 100 nm to allow some margin because the oscillation wavelength may also vary to the longer wavelength side with respect to the target. The same estimate can also be made for the case in which the propagation light is a transverse magnetic (TM) wave.

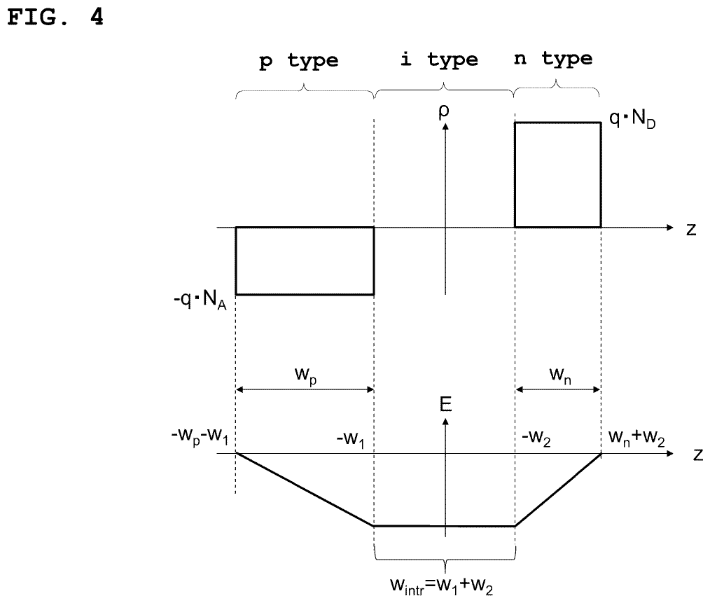

FIG. 5 illustrates the simulation results of the propagation mode of the nitride semiconductor light-emitting device of the first embodiment. In FIG. 5, the simulation was performed for the structure of FIG. 2A with the thickness of the p-side layer set to 100 nm, and it was found that the light propagation mode is sufficiently confined in the longitudinal direction when the thickness of the p-side layer was approximately 100 nm. Hence, even when the thickness of the A-side layer remains thin, the light propagation mode can be sufficiently confined in the longitudinal direction, thereby resulting in the low resistance and low optical loss of the semiconductor laser LA.

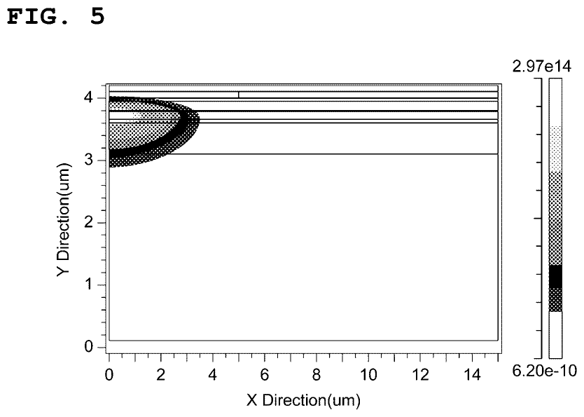

FIG. 6A is a cross-sectional view illustrating the configuration example of a nitride semiconductor light-emitting device according to a comparative example, cut along the light-waveguide direction, and FIG. 6B illustrates a diagram illustrating the refractive index of each layer of the nitride semiconductor light-emitting device according to the comparative example. In FIG. 6A, a semiconductor laser LB includes a p-type nitride semiconductor layer N2′ instead of the p-type nitride semiconductor layer N2 of the semiconductor laser LA in FIG. 2A. Part of the p-type nitride semiconductor layer N2′ is provided with a current constriction layer 33.

An electrode 35 is formed on the p-type nitride semiconductor layer N2′. An end-face-protective layer 36 is formed on the end face EF of the semiconductor laser LB, and an end-face-protective layer 37 is formed on the end face ER of the semiconductor laser LB.

The p-type nitride semiconductor layer N2′ includes the p-type carrier block layer 17, a p-type nitride guide layer 31, a p-type nitride cladding layer 32, and a p-type nitride contact layer 34. The p-type carrier block layer 17, the p-type nitride guide layer 31, the p-type nitride cladding layer 32, and the p-type nitride contact layer 34 are sequentially stacked on the non-doped nitride guide layer 16.

For example, a p-type GaN layer, a p-type Al_{0.02}Ga_{0.98}N layer, and a p-type GaN layer can be used as the p-type nitride guide layer 31, the p-type nitride cladding layer 32, and the p-type nitride contact layer 34, respectively. As shown in FIG. 6B, the refractive index of the p-type nitride cladding layer 32 can be smaller than that of the p-type nitride guide layer 31 and p-type nitride contact layer 34.

If the p-type nitride cladding layer 32 does not have a certain thickness, the light propagation mode is shifted toward the p-type nitride contact layer 34, resulting in a decrease in light amplification efficiency. Also, if the p-type nitride cladding layer 32 does not have a certain thickness, the light propagation mode propagates the electrode 35, resulting in an increase in optical loss. Hence, when the thickness of the p-type nitride contact layer 34 is 100 nm and N_{A}=1×10¹⁸/cm³, the p-type nitride cladding layer 32 needs to have a thickness of 585 nm or more because n_{clad} is ≈2.51 in the case where the p-type nitride cladding layer 32 is a p-type Al_{0.02}Ga_{0.98}N layer.

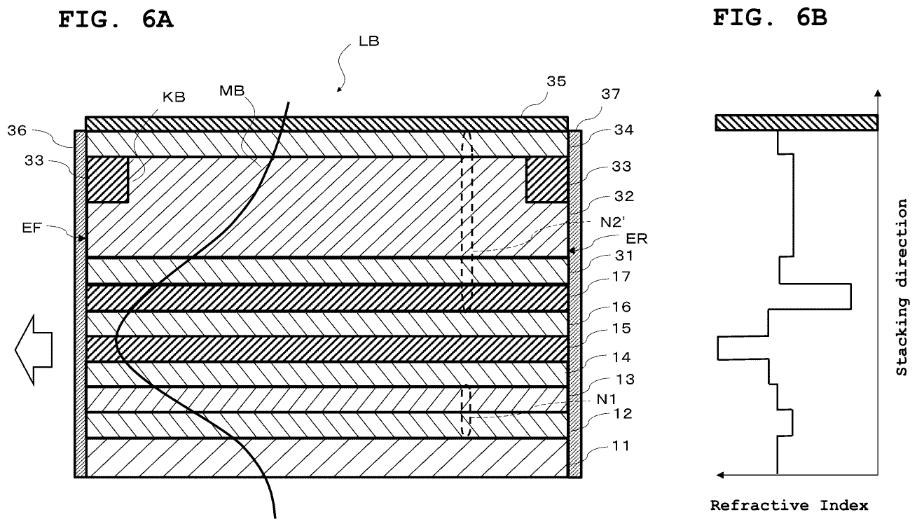

FIG. 7A illustrates an example of simulation results of the propagation mode of the nitride semiconductor light-emitting device for the comparative example. In FIG. 7A, the simulation was performed for the structure of FIG. 6A with the thickness of the p-type nitride semiconductor layer N2′ set to 700 nm. In this case, the light propagation mode seeps slightly toward the electrode 35 side as the resistance increases because the thickness of the p-type nitride semiconductor layer N2′ is large.

FIG. 7B illustrates another example of simulation results of the propagation mode of the nitride semiconductor light-emitting device according to the comparative example. In FIG. 7B, the simulation was performed for the structure of FIG. 6A with the thickness of the p-type nitride semiconductor layer N2′ set to 100 nm. In this case, the light propagation mode propagates the electrode 35, expecting an increase in the propagation loss.

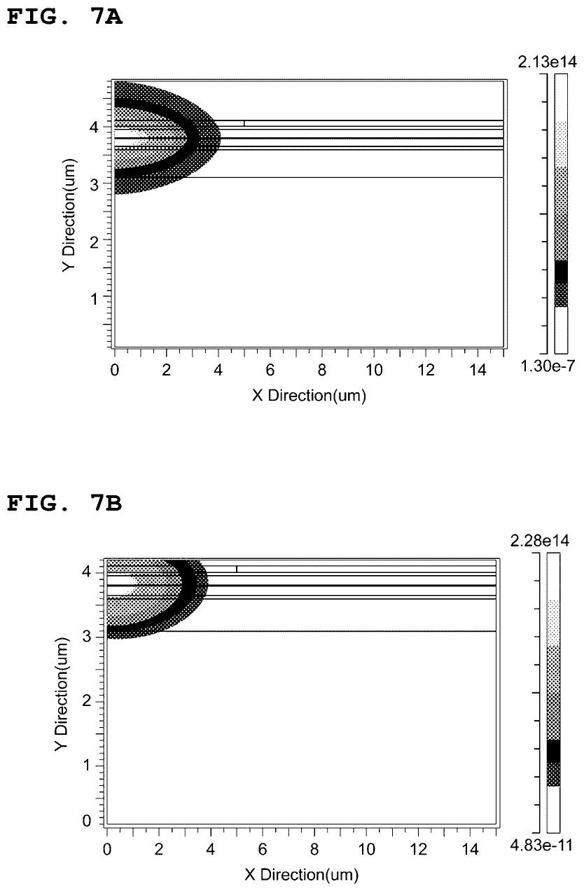

FIG. 8 is a cross-sectional view illustrating an implementation example of the nitride semiconductor light-emitting device according to the first embodiment. In FIG. 8, the semiconductor laser LA is mounted on a submount MT by a junction-down bonding. The material of the submount MT is, for example, SiC. The semiconductor laser LA is connected to the submount MT by using Au—Sn solder HD, for example.

The semiconductor laser LA, which is of an inner stripe type, can flatten the electrode 21 in FIG. 1. Hence, even when the semiconductor laser LA is mounted by a junction-down bonding, it is possible to alleviate the concentration of external stress in a specific area in the semiconductor laser LA, thereby improving reliability. In addition, mounting the semiconductor laser LA by a junction-down bonding makes it possible to improve the heat dissipation properties of the semiconductor laser LA, increasing the laser output power.

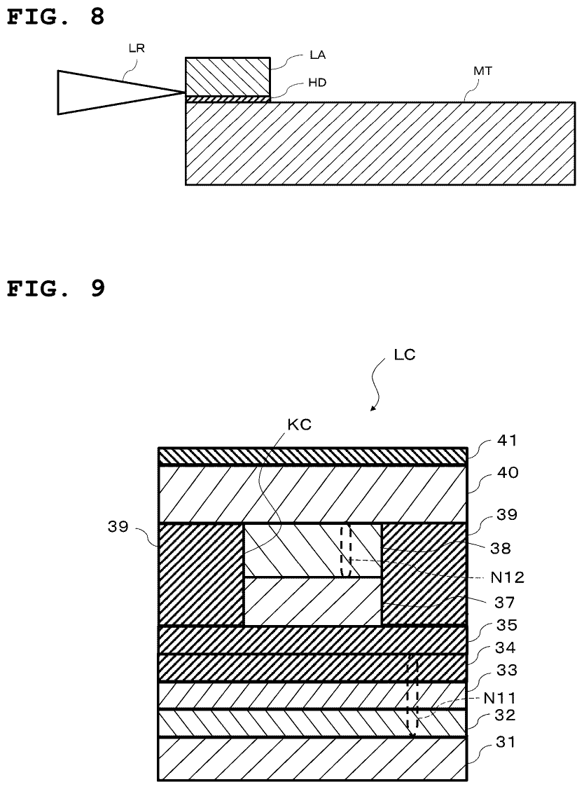

FIG. 9 is a cross-sectional view illustrating a configuration of a nitride semiconductor light-emitting device according to a second embodiment, cut perpendicular to the light-waveguide direction. In FIG. 9, a semiconductor laser LC includes a p-type nitride semiconductor layer N11, an active layer 35, an n-type nitride semiconductor layer N12, a current constriction layer 39, and a transparent conductive layer 40. The active layer 35 is stacked on the p-type nitride semiconductor layer N11. The n-type nitride semiconductor layer N12 is stacked over the active layer 35. The n-type nitride semiconductor layer N12 preferably has a thickness of 5 nm or more and 150 nm or less.

In order to suppress the diffusion of impurities from the n-type nitride semiconductor layer N12 to the active layer 35, a non-doped nitride guide layer 37 may be provided between the n-type nitride semiconductor layer N12 and the active layer 35.

The current constriction layer 39 is located in a part of the n-type nitride semiconductor layer N12. The current constriction layer 39 may extend from the n-type nitride semiconductor layer N12 to the non-doped nitride guide layer 37. The current constriction layer 39 can be located in a part of the n-type nitride semiconductor layer N12 and the non-doped nitride guide layer 37 such that at least one resonator of the refractive index waveguide type or the gain waveguide type is configured. The planar shape of the current constriction layer 39 can be set as shown in FIG. 3C. The current constriction layer 39 can be, for example, a high-resistance layer made of AlN. The thickness of the current constriction layer 39 can be, for example, equal to the sum of the thickness of the n-type nitride semiconductor layer N12 and the thickness of the non-doped nitride guide layer 37. For example, the thickness of the current constriction layer 39 can be set to 150 nm.

The transparent conductive layer 40 is a conductive layer transparent to the light generated from the active layer 35. The transparent conductive layer 40 can have its Fermi level located in the conduction band. The transparent conductive layer 40 is used as at least one of a guide layer or a cladding layer over the active layer 35. The transparent conductive layer 40 can contain at least one element selected from among In, Sn, Zn, Ti, Nb, and Zr, and can be an oxide of these elements. The transparent conductive layer 40 is preferably thinned to the extent that the vertical transverse mode, which is the propagation mode in a direction vertical to the light propagation direction, can be confined therein. The thickness of the transparent conductive layer 40 is preferably from 80 nm or more and 120 nm or less. In the present specification, the n-type nitride semiconductor layer N12 and the transparent conductive layer 40 together may be referred to as an n-side layer.

The p-type nitride semiconductor layer N11 includes the p-type nitride cladding layer 32, a p-type nitride guide layer 33, and a p-type carrier block layer 34. The p-type nitride cladding layer 32, the p-type nitride guide layer 33, and the p-type carrier block layer 34 are sequentially stacked on a p-type nitride semiconductor substrate 31.

The n-type nitride semiconductor layer N12 includes an n-type nitride guide layer 38. The n-type nitride guide layer 38 is stacked on the non-doped nitride guide layer 37. Here, in order to dispose the current constriction layer 39 in a part of the non-doped nitride guide layer 37 and the n-type nitride guide layer 38, an opening KC may be formed in the current constriction layer 39 to sequentially embed the non-doped nitride guide layer 37 and the n-type nitride guide layer 38 in the opening KC.

An electrode 41 is formed on the transparent conductive layer 40 to inject the current into the active layer 35 through the transparent conductive layer 40 and the p-type nitride semiconductor layer N12. The electrode 41 can have a layered structure of Ti/Pt/Au. The thickness of Ti/Pt/Au can be set to 100/50/300 nm, for example.

End-face-protective layers are formed on the front end face and rear end face of the semiconductor laser LC. The end-face-protective layer on the front end face of the semiconductor laser LC can have a layered structure of AlN/SiO₂; the thickness of the AlN/SiO₂ can be set to 30/300 nm, for example. The end-face-protective layer on the rear end face of the semiconductor laser LC can have a layered structure of AlN/(SiO₂/Ta₂O₅)⁶/SiO₂. The thickness of AlN/(SiO₂/Ta₂O₅)⁶/SiO₂ can be set to 30/(60/40)⁶/10 nm, for example. The end-face-protective layers can cover not only the respective end faces of the p-type nitride semiconductor layer N11, the active layer 35, the n-type nitride semiconductor layer N12, and the current constriction layer 39, but also the end face of the transparent conductive layer 40.

As the p-type nitride semiconductor substrate 31, the p-type nitride cladding layer 32, the p-type nitride guide layer 33, the p-type nitride carrier block layer 34, the active layer 35, the non-doped nitride guide layer 37 and the n-type nitride guide layer 38, for example, a p-type GaN substrate, a p-type Al_{0.02}Ga_{0.98}N layer, a p-type GaN layer, a p-type Al_{0.22}Ga_{0.78}N layer, a multiple quantum well layer consisting of an In_{0.02}Ga_{0.98}N layer/an In_{0.08}Ga_{0.88}N layer/an In_{0.02}Ga_{0.98}N layer/an In_{0.08}Ga_{0.88}N layer/an In_{0.02}Ga_{0.98}N layer/an In_{0.08}Ga_{0.88}N layer/an In_{0.02}Ga_{0.98}N layer, a GaN layer, and a p-type GaN layer can be used, respectively.

The thickness of the p-type nitride cladding layer 32 can be set to 500 nm, for example, and the acceptor concentration N_{A} thereof can be set to 1×10¹⁸/cm³. The thickness of the n-type nitride guide layer 33 can be set to 36 nm, for example, and the acceptor concentration N_{A} thereof can be set to 1×10¹⁸/cm³. The thickness of the p-type carrier block layer 34 can be set to 4 nm, for example, and the acceptor concentration N A thereof can be set to 1×10¹⁸/cm³. The thickness of the barrier layer/well layer/barrier layer/well layer/barrier layer/well layer/barrier layer of the quantum well layer of the active layer 35 can be set to 10/9/10/9/10/9/10 nm, for example. The thickness of the non-doped nitride guide layer 37 can be set to 33 nm, for example. The thickness of the p-type nitride guide layer 38 can be set to 117 nm, for example, and the donor concentration N D thereof can be set to 1×10¹⁷/cm³, for example. The thickness of the n-type nitride semiconductor layer N12 and the transparent conductive layer 40 can be determined by a method similar to that in the first embodiment.

Here, the refractive index of the p-type nitride cladding layer 32 can be smaller than that of the p-type nitride guide layer 33. The refractive index of the p-type carrier block layer 34 can be smaller than that of the p-type nitride cladding layer 32. The refractive index of the transparent conductive layer 40 can be smaller than that of the n-type nitride guide layer 38, the refractive index of the n-type nitride guide layer 38 can be smaller than that of the non-doped nitride guide layer 36, and the refractive index of the non-doped nitride guide layer 37 can be smaller than that of the active layer 35.

Here, setting the refractive index of the transparent conductive layer 40 to be smaller than that of the n-type nitride guide layer 38 makes it possible to confine the vertical transverse mode with the transparent conductive layer 40 while suppressing the n-type nitride semiconductor layer N12 from being thickened. In addition, stacking the transparent conductive layer 40 on the n-type nitride semiconductor layer N12 eliminates the need for providing an n-type nitride semiconductor contact layer on the transparent conductive layer for making contact with the electrode 41 and reduces the resistance on the current injected into the active layer 35 through the transparent conductive layer 40. Furthermore, providing the current constriction layer 39 in a part of the n-type nitride semiconductor layer N12 makes it possible to constrict the current injected into the active layer 35 with the current constriction layer 39, thereby confining the horizontal transverse mode, which is in a direction horizontal to the light propagation direction, between the current constriction layers 39 in addition to efficiently injecting the current into the light-emitting area. This makes it possible to reduce optical loss in addition to reducing the heat generation in the nitride semiconductor laser LC during the light propagation, thereby improving the slope efficiency.

Setting the thickness of the n-type nitride semiconductor layer N12 to 5 nm or more makes it possible to secure the depletion layer necessary for recombination in the n-type nitride semiconductor layer N12, thereby preventing a decrease in luminous efficiency. Setting the thickness of the n-type nitride semiconductor layer N12 to 150 nm or less makes it possible to reduce the resistance on the current injected into the active layer 35 through the n-type nitride semiconductor layer N12, thereby reducing the heat generation of the semiconductor laser LC.

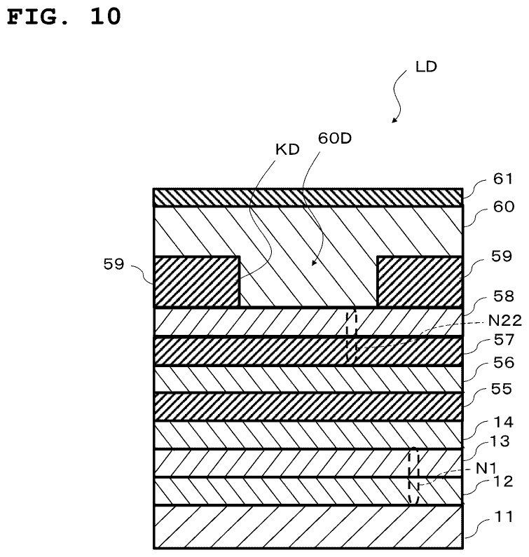

FIG. 10 is a cross-sectional view illustrating a nitride semiconductor light-emitting device of a third embodiment, cut perpendicular to the light-waveguide direction. In FIG. 10, the semiconductor laser LD includes an active layer 55, a p-type nitride semiconductor layer N22, a current constriction layer 59, and a transparent conductive layer 60 instead of the active layer 15, the p-type nitride semiconductor layer N2, the current constriction layer 19, and the transparent conductive layer 20 of the semiconductor laser LA in FIG. 1. The active layer 55 is stacked on the n-type nitride semiconductor layer N1. The p-type nitride semiconductor layer N22 is stacked on the active layer 15.

In order to suppress the diffusion of impurities from the n-type nitride semiconductor layer N1 to the active layer 55, the non-doped nitride guide layer 14 may be provided between the n-type nitride semiconductor layer N1 and the active layer 55. In order to suppress the diffusion of impurities from the p-type nitride semiconductor layer N22 to the active layer 55, a non-doped nitride guide layer 56 may be provided between the p-type nitride semiconductor layer N12 and the active layer 55.

The current constriction layer 59 is located in a part of the transparent conductive layer 60. The current constriction layer 59 can be located in a part of the transparent conductive layer 60 such that a resonator of the gain waveguide type is configured. The current constriction layer 59 can also be located over the light-emitting section of the active layer 55 on the end-face side of the p-type nitride semiconductor layer N22. The current constriction layer 59 can be, for example, a high-resistance layer made of AlN. The thickness of the current constriction layer 59 can be set to 100 nm, for example.

The transparent conductive layer 60 is a conductive layer transparent to light generated from the active layer 55. The transparent conductive layer 60 can have its Fermi level located in the conduction band. The transparent conductive layer 60 is used as at least one of a guide layer or a cladding layer over the active layer 55. The transparent conductive layer 60 can include at least one element selected from among In, Sn, Zn, Ti, Nb, and Zr, and can be an oxide of these elements. The transparent conductive layer 60 is preferably thinned to the extent that the vertical transverse mode can be confined therein. Here, in order to dispose the current constriction layer 59 on a part of the transparent conductive layer 60, an opening KD may be formed in the current constriction layer 59 to embed the transparent conductive layer 60D in the opening KD.

The p-type nitride semiconductor layer N22 includes the p-type carrier block layer 57 and a p-type nitride guide layer 58. The p-type carrier block layer 57 and the p-type nitride guide layer 58 are sequentially stacked on the non-doped nitride guide layer 56.

An electrode 61 is formed to inject the current into the active layer 55 through the transparent conductive layer 60 and the p-type nitride semiconductor layer N22 on the transparent conductive layer 60. The electrode 61 can be a layered structure of Ti/Pt/Au. The thickness of Ti/Pt/Au can be set to 100/50/300 nm, for example.

End-face-protective layers are formed on the front end face and rear end face of the semiconductor laser LD. The end-face-protective layer on the front end face of the semiconductor laser LD can have a layered structure of AlN/SiO₂; the thickness of the AlN/SiO₂ can be set to 30/300 nm, for example. The end-face-protective layer on the rear end face of the semiconductor laser LD can have a layered structure of AlN/(SiO₂/Ta₂O₅)⁶/SiO₂; the thickness of AlN/(SiO₂/Ta₂O₅)⁶/SiO₂ can be set to 30/(60/40)⁶/10 nm, for example. The end-face-protective layers can cover not only the respective end faces of the p-type nitride semiconductor layer N1, the active layer 55, the n-type nitride semiconductor layer N22, and the current constriction layer 59, but also the end face of the transparent conductive layer 60.

As the active layer 55, the non-doped nitride guide layer 56, the p-type carrier block layer 57 and the p-type nitride guide layer 58, for example, a double quantum well layer consisting of an In_{0.02}Ga_{0.98}N layer/an In_{0.08}Ga_{0.88}N layer/an In_{0.02}Ga_{0.98}N layer/an In_{0.08}Ga_{0.88}N layer/an In_{0.02}Ga_{0.98}N layer, an In_{0.02}Ga_{0.99}N layer, a p-type Al_{0.22}Ga_{0.78}N layer, and a p-type GaN layer can be used, respectively.

The thickness of the barrier layer/well layer/barrier layer/well layer/barrier layer of the quantum well layer of the active layer 55 can be set to 10/9/10/9/10 nm, for example. The thickness of the non-doped nitride guide layer 16 can be set to 126 nm, for example. The thickness of the p-type carrier block layer 17 can be set to 4 nm, and the acceptor concentration N_{A} thereof can be set to 1×10¹⁸/cm³, for example. The thickness of the p-type nitride guide layer 18 can be set to 150 nm and the acceptor concentration N A thereof can be set to 1×10¹⁸/cm³, for example.

The refractive index of the transparent conductive layer can be smaller than that of the p-type nitride guide layer 58, the refractive index of the p-type nitride guide layer 58 can be smaller than that of the non-doped nitride guide layer 56, and the refractive index of the non-doped nitride guide layer 56 can be smaller than that of the active layer 55. The refractive index of the p-type carrier block layer 57 can be smaller than that of the p-type nitride guide layer 58.

Here, setting the refractive index of the transparent conductive layer 60 to be smaller than that of the p-type nitride guide layer 58 and covering the end faces of the transparent conductive layer 60 with the end-face-protective layers makes it possible to reflect the guided light with the end-face-protective layers while maintaining the distribution of the vertical transverse mode, in addition to making it to possible to confine the vertical transverse mode with the transparent conductive layer 60 while suppressing the p-type nitride semiconductor layer N2 from being thickened. In addition, stacking the transparent conductive layer 60 on the p-type nitride semiconductor layer N22 eliminates the need for providing a p-type nitride semiconductor contact layer on the transparent conductive layer 60 for making contact with the electrode 61 and reduces the resistance on the current injected into the active layer 55 through the transparent conductive layer 60. Furthermore, providing the current constriction layer 59 in a part of the transparent conductive layer 60 makes it possible to constrict the current injected into the active layer 55 with the current constriction layer 59 without performing another crystal growth after the formation of the current constriction layer 60, thereby efficiently injecting the current into the light-emitting area. This makes it possible to reduce optical loss during the light propagation in addition to reducing the heat generation in the nitride semiconductor laser LD while suppressing an increase in the number of processes, thereby improving the slope efficiency.

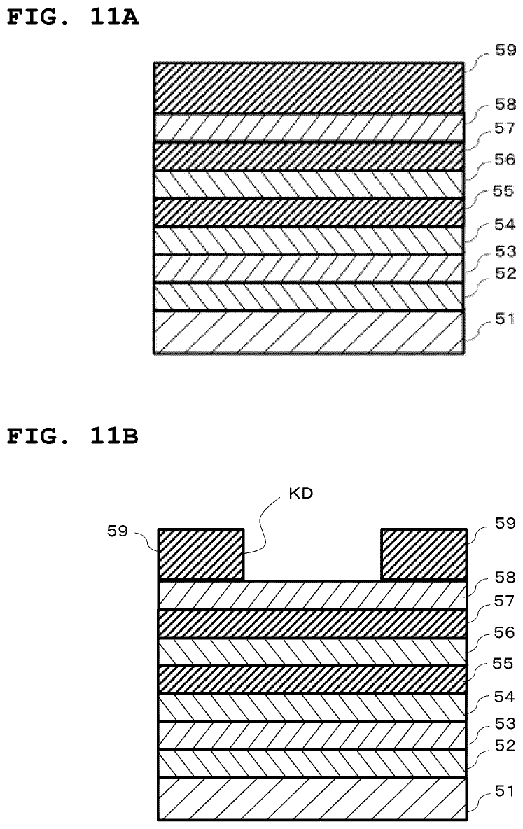

FIGS. 11A and 11B each are a cross-sectional view illustrating an example of a method of manufacturing the nitride semiconductor light-emitting device according to the third embodiment. In FIG. 11A, an n-type nitride cladding layer 52, an n-type nitride guide layer 53, a non-doped nitride guide layer 54, the active layer 55, a non-doped nitride guide layer 56, a p-type carrier block layer 57 and a p-type nitride guide layer 58 are sequentially stacked on an n-type nitride semiconductor substrate 51 by epitaxial growth. In addition, the current constriction layer 59 is stacked on the p-type nitride guide layer 58 by epitaxial growth, sputtering, or other methods. The thickness of the p-type nitride semiconductor layer N22 and the transparent conductive layer 60 can be determined by a method similar to that in the first embodiment.

Next, as shown in FIG. 11B, the current constriction layer 59 is patterned using photolithography and dry etching techniques to form the opening KD in the current constriction layer 59. The planar shape of the current constriction layer 59 can be set as shown in FIG. 3C.

Next, as shown in FIG. 10, the transparent conductive layer is formed on the p-type nitride guide layer 58 and the current constriction layer 59 to be embedded in the opening KD by sputtering or other methods. Then, the electrode 61 is formed on the transparent conductive layer 60 by vapor deposition or other methods. Then, end faces with cleaved surfaces are formed by cleaving the n-type nitride semiconductor substrate 11. Then, the end-face-protective layers are formed on the respective end faces by sputtering or other methods.

### REFERENCE SIGNS LIST

N1 n-type nitride semiconductor layer
N2 p-type nitride semiconductor layer
11 n-type nitride semiconductor substrate
12 n-type nitride cladding layer
13 n-type nitride guide layer
14, 16 Non-doped nitride guide layer
15 Active layer
17 p-type carrier block layer
18 p-type nitride guide layer
19 Current constriction layer
Transparent conductive layer
21 Electrode
22 End-face-protective layer

1. A nitride semiconductor light-emitting device comprising:
a first conductivity-type nitride semiconductor layer;
an active layer located over the first conductivity-type nitride semiconductor layer;
a second conductivity-type nitride semiconductor layer located over the active layer;
a current constriction layer located in a part of the second conductivity-type nitride semiconductor layer; and
a transparent conductive layer located on the second conductivity-type nitride semiconductor layer and transparent to light generated from the active layer.

2. The nitride semiconductor light-emitting device according to claim 1, further comprising an end-face-protective layer formed on each end face of the first conductivity-type nitride semiconductor layer, the active layer, the second conductivity-type nitride semiconductor layer, and the transparent conductive layer.

3. The nitride semiconductor light-emitting device according to claim 1, wherein a lower face of the current constriction layer is set at a position lower than an upper face of the second conductivity-type nitride semiconductor layer.

4. The nitride semiconductor light-emitting device according to claim 1, wherein the current constriction layer is formed to have an opening along a light-waveguide direction in which the light generated from the active layer is guided, and the second conductivity-type nitride semiconductor layer is embedded in the opening.

5. A nitride semiconductor light-emitting device comprising:
a first conductivity-type nitride semiconductor layer;
an active layer located over the first conductivity-type nitride semiconductor layer;
a second conductivity-type nitride semiconductor layer located over the active layer;
a transparent conductive layer located on the second conductivity-type nitride semiconductor layer and transparent to light generated from the active layer;
a current constriction layer located in a part of the transparent conductive layer; and
an end-face-protective layer formed on each end face of the first conductivity-type nitride semiconductor layer, the active layer, the second conductivity-type nitride semiconductor layer, and the transparent conductive layer.

6. The nitride semiconductor light-emitting device according to claim 1, wherein the transparent conductive layer is used as at least one of a guide layer or a cladding layer over the active layer.

7. The nitride semiconductor light-emitting device according to claim 1, wherein the current constriction layer is also located over a light-emitting section of the active layer on an end-face side of the second conductivity-type nitride semiconductor layer.

8. The nitride semiconductor light-emitting device according to claim 7, wherein the current constriction layer is located along the light-waveguide direction and is continuous on the end-face side of the second conductivity-type nitride semiconductor layer.

9. The nitride semiconductor light-emitting device according to claim 1, wherein the second conductivity-type nitride semiconductor layer extends between the current constriction layer and the active layer.

10. The nitride semiconductor light-emitting device according to claim 1, wherein the first conductivity-type nitride semiconductor layer is an n-type nitride semiconductor layer, and the second conductivity-type nitride semiconductor layer is a p-type nitride semiconductor layer.

11. The nitride semiconductor light-emitting device according to claim 10, wherein the p-type nitride semiconductor layer at a position where the current constriction layer is absent has a thickness of 40 nm or more and 550 nm or less.

12. The nitride semiconductor light-emitting device according to claim 1, wherein the first conductivity-type nitride semiconductor layer is a p-type nitride semiconductor layer and the second conductivity-type nitride semiconductor layer is an n-type nitride semiconductor layer.

13. The nitride semiconductor light-emitting device according to claim 12, wherein the n-type nitride semiconductor layer at a position where the current constriction layer is absent has a thickness of 5 nm or more and 150 nm or less.

14. The nitride semiconductor light-emitting device according to claim 1, wherein the transparent conductive layer contains at least one element selected from among In, Sn, Zn, Ti, Nb, and Zr.

15. The nitride semiconductor light-emitting device according to claim 1, wherein the transparent conductive layer is thinned in a range in which a vertical transverse mode is able to be confined during light propagation.

16. The nitride semiconductor light-emitting device according to claim 1, wherein the transparent conductive layer has a thickness of 80 nm or more and 120 nm or less.

17. The nitride semiconductor light-emitting device according to claim 5, wherein the transparent conductive layer is used as at least one of a guide layer or a cladding layer over the active layer.

18. The nitride semiconductor light-emitting device according to claim 5, wherein the current constriction layer is also located over a light-emitting section of the active layer on an end-face side of the second conductivity-type nitride semiconductor layer.

19. The nitride semiconductor light-emitting device according to claim 5, wherein the second conductivity-type nitride semiconductor layer extends between the current constriction layer and the active layer.
